(19) United States
(12) Patent Application Publication
(10) Pub. No.: US 2012/0023841 A1
(43) Pub. Date: Feb. 2, 2012

(54) MULTI-FUNCTIONAL SOLAR ENERGY CONVERSION ROOFTOP TILING SYSTEM

(75) Inventor: CROCIFISSO MARCO ANTONIO RENNA, Gela (IT)

(73) Assignee: STMicroelectronics S.r.I, Agrate Brianza (IT)

(21) Appl. No.: 13/190,718

(22) Filed: Jul. 26, 2011

(30) Foreign Application Priority Data
Jul. 29, 2010 (IT) VA2010A000057

(51) Int. Cl. E04D 13/18; H05K 13/00

(52) U.S. Cl. 52/173.3; 29/592.1

(57) ABSTRACT

A rooftop tiling system may include multi-functional roof tiles integrating photovoltaic and thermal converters for solar energy. The tiles allow a heat transfer fluid to circulate through inner flow channels of the tiles, and light concentration photovoltaic modules may be present atop the tiles together with a transmission or light reflection focusing device.

### FIELD OF THE INVENTION

This disclosure relates in general to photovoltaic systems and, more particularly, to light-concentration photovoltaic and thermal conversion systems of solar energy, integrated in a rooftop.

### BACKGROUND OF THE INVENTION

Installation of photovoltaic and/or thermal panels onto the rooftop of a residential or commercial building for converting solar energy into electrical energy, and/or for heating water for interior heating and/or sanitary services in the building, is a well known practice. Tiling of photovoltaic and thermal panels on rooftops remains, in most cases, reserved to a certain area of the rooftop free of skylights, chimney cowls, vents and other fixtures, and the laying of panels adds noticeable discontinuities in the tiling.

### SUMMARY OF THE INVENTION

An object of the present disclosure is to provide a combined-function solar energy conversion system including tiles that are adapted to generate electrical energy by photovoltaic conversion of concentrated light, for providing enhanced conversion efficiency of solar radiation incident a rooftop, and simultaneously absorbing heat energy from the rooftop heated by the sun. This is done by circulating inside the tiling an appropriate fluid (e.g., the primary fluid of a heat exchanger) that heats water for building services or incoming cool water from a public distribution network or other source for storage and use as hot sanitary water.

The system of the present disclosure is modular, allowing utilization of greater rooftop surface area or favorably oriented slopes, and around functional fixtures.

The system includes rooftop tiles, which may be shaped and laid out similar to other traditional rooftop tiles. Each tile has inner flow channels for a heat transfer fluid as well as a mono or multi-cellular photovoltaic conversion module, and an optical means or device adapted to concentrate incident solar radiation onto the active light sensing area or areas of the cells of the photovoltaic module.

Moreover, each tile may be provided with snap-on (i.e., quick-action or quick-connect) hydraulic nipples and weather proof electrical connectors for connecting to respective hydraulic and electrical circuits. Common mounts and mutual locking or grip features may be provided for relatively easy mechanical anchoring or coupling together of tiles of different columns oriented along the slope directions of the roof, and to the respective flanking tiles of adjacent columns.

Hydraulic manifolds may also be provided for distributing and collecting the heat transfer fluid, which may flow serially through the inner channels of the tiles of each of column of tiles on a rooftop slope. Furthermore, electrical common buses (e.g., positive and negative) for electrical current generated by the photovoltaic modules may connect the tiles of each column in series along a slope of the roof. The electrical busses and manifolds may be installed along the lower edge or base of the slope and along the upper edge or vertex of the slope for conveying the generated electrical power and the heated fluid to a photovoltaic field switchboard and to a hot water storage tank or to a heat exchanger, respectively.

### BRIEF DESCRIPTION OF THE DRAWINGS

Various features of the system will become evident through the following description of several embodiments and with reference to the attached drawings, wherein:

FIG. 1 is a three-dimensional (3D) schematic sectional view of a first embodiment of a tile of the present disclosure that may be modularly joined to other identical tiles to cover the rooftop of a building;

FIG. 2 is a (3D) schematic sectional view of the tile of FIG. 1 illustrating the concentrating lens function of a transparent cap of the tile;

FIG. 3 is a (3D) schematic view illustrating a plurality of the modular tiles of FIG. 1 laid or coupled together on a rooftop slope;

FIG. 4 is a schematic diagram illustrating exemplary electrical and hydraulic connection couplings between two adjacent tiles in accordance with an embodiment the invention;

FIG. 5 is a schematic diagram illustrating an alternative embodiment of electrical connection couplings of the photovoltaic modules of FIG. 4;

FIG. 6 is perspective view of a weather proof connector used for connecting the photovoltaic modules of tiles of FIG. 1 in series to be laid one next to the other along the slope of a rooftop;

FIG. 7 is a partial schematic view of a rooftop installation of a plurality of the panels of FIG. 1 with respective electrical buses and hydraulic manifolds running at the base and at the vertex of the rooftop slope;

FIG. 8 is a schematic view of an alternative embodiment of the tile of FIG. 1 implementing a reflection concentration of incident solar light onto the active areas of the photovoltaic module of the tile instead of employing a transmission lens;

FIG. 9 is a schematic view of the tile of FIG. 8 along with an actuator device for modifying the angle of incidence of solar radiation onto the reflecting surface of the tile;

FIG. 10 is a schematic view of a modular arrangement of the tiles of FIG. 8 adapted to make the reflective surface of a tile illuminate the cells of the photovoltaic module of the (sideways) adjacent tile;

FIG. 11 is a partial schematic view illustrating a modular arrangement for laying the tiles of FIG. 8 in two orthogonal directions of a rooftop slope;

FIG. 12 is a 3D schematic view illustrating snap-on electrical and hydraulic connection joints between two of the tiles of FIG. 8 laid adjacent along a slope of a rooftop.

### DETAILED DESCRIPTION OF THE PREFERRED EMBODIMENTS

The drawings and the ensuing detailed description of exemplary embodiments shown in the figures are provided for illustrative purposes and are not intended to limit the scope of protection as defined in the annexed claims, as other embodiments are possible for meeting particular requirements or design choices of the tile-level modular photovoltaic and thermal conversion system of the present disclosure, providing for the fullest integration in a sloped rooftop building tile installation.

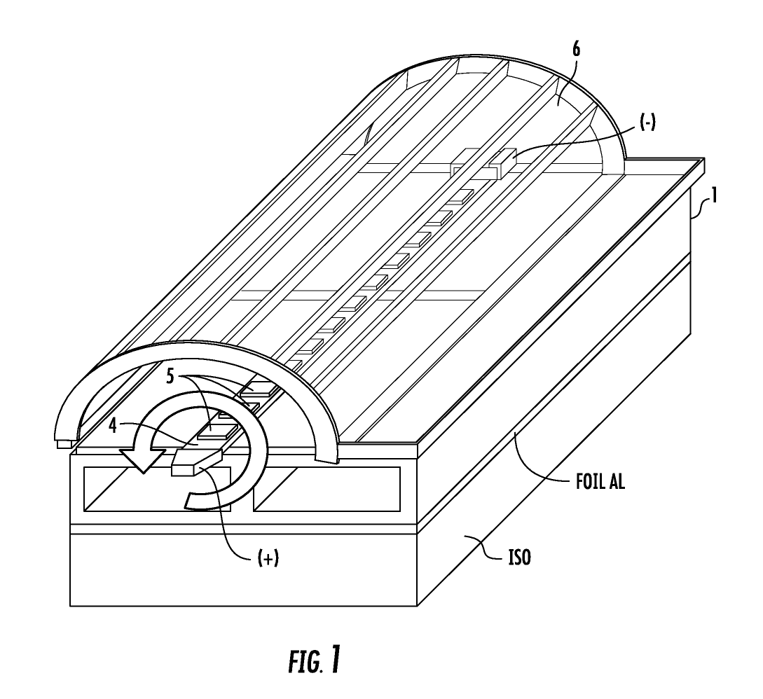

A first exemplary embodiment of the system of the present disclosure is now described with reference to FIGS. 1 to 7. In the illustrated system, the tiles are laid modularly in columns and rows of tiles interconnected with one another, from the base of the slope up to the vertex of the slope. The tiles have a parallelepiped body 1, generally with a substantially rectangular footprint, and may be laid on a blanket layer of thermo or thermal isolation ISO. The thermo isolation ISO is typically of expanded or fibrous material topped by a reflective film or foil FOIL-Al, which may, for example, be of expanded polyurethane, rock wool or equivalent isolation material, covered by a reflective film, e.g., a thin aluminum foil.

The body 1 of the tiles may be hollow to define at its interior one or more flow channels for a heat transfer fluid. In the exemplary embodiment shown, two parallel channels 2 and 3 are defined through the tile body, oriented in the direction of inclination of the rooftop slope. The flow channels 2 and 3 extend from a lower end wall of the body 1 to an upper end wall (not visible in the sectional three-dimensional view of FIG. 1).

In the parallel channels 2 and 3, water may circulate to be heated for sanitary uses. Alternatively, a different heat transfer fluid may be circulated that has a large heat absorption capacity for transferring heat to water to be heated within a heat exchanger that may be located elsewhere in the building (e.g., loft or attic, cellar, etc.). In accordance with another embodiment, within the hollow tile body 1 a pipe coil may be incorporated for forced circulation of a heat transfer fluid as the primary circuit of a heat exchanger for heating water for sanitary use in the building, or for space heating of the building interiors.

As will be described in more detail below, through the respective lower and upper end walls of the hollow tile body quick-action (snap-on) hydraulic couplings may be installed for inlet and outlet, respectively, facilitating hydraulic connection of flow channels of adjacent tiles of a column of tiles oriented in the slope direction, and eventually to respective inlet and outlet manifolds that may be installed, respectively, along the vertex and the base of the rooftop slope.

The hollow tile body 1 may be made of any suitable material that is resistant to atmospheric agents and solar radiation, such as with a relatively large thermal mass. Moreover, its upper surface may have a dark tonality to maximize absorption of light energy from the incident solar radiation in the form of heat, which is absorbed by the heat transfer fluid circulating through the inner flow channel or channels of the tile.

Preferably, the body 1 may comprise a moldable material, e.g., a thermoplastic material, which may include particulated carbon, ceramic and/or metal and optionally be reinforced with glass or carbon fibers.

Along a strip of the upper surface of the hollow body 1 of each tile is installed a pluricellular photovoltaic module 4, which in the illustrated example comprises a plurality of high efficiency photovoltaic cells 5 connected in series between a (anodic) negative terminal (−) in the lower or upper end wall of the tile and a (cathodic) positive terminal (+) in the other end wall, or vice versa. This provides a series connection between the photovoltaic modules 4 of all the tiles of a column of tiles along the slope direction to a negative bus (−) and to a positive bus (+) corresponding to the base and vertex of the slope, or vice versa. The electrical buses (−) and (+) may be connected to the photovoltaic modules of all or certain groups of columns of tiles flanking one another in a sideways or side-by-side direction of extension of the rooftop slope, from one flank to another.

Of course, the plurality of multi-cellular photovoltaic modules 4 of tiles may be made connectable according to any desired series or parallel scheme at an appropriate photovoltaic field switchboard. The switchboard may be arranged at the input of an inverter for converting the DC voltage to standard AC voltage and frequency of the electrical mains.

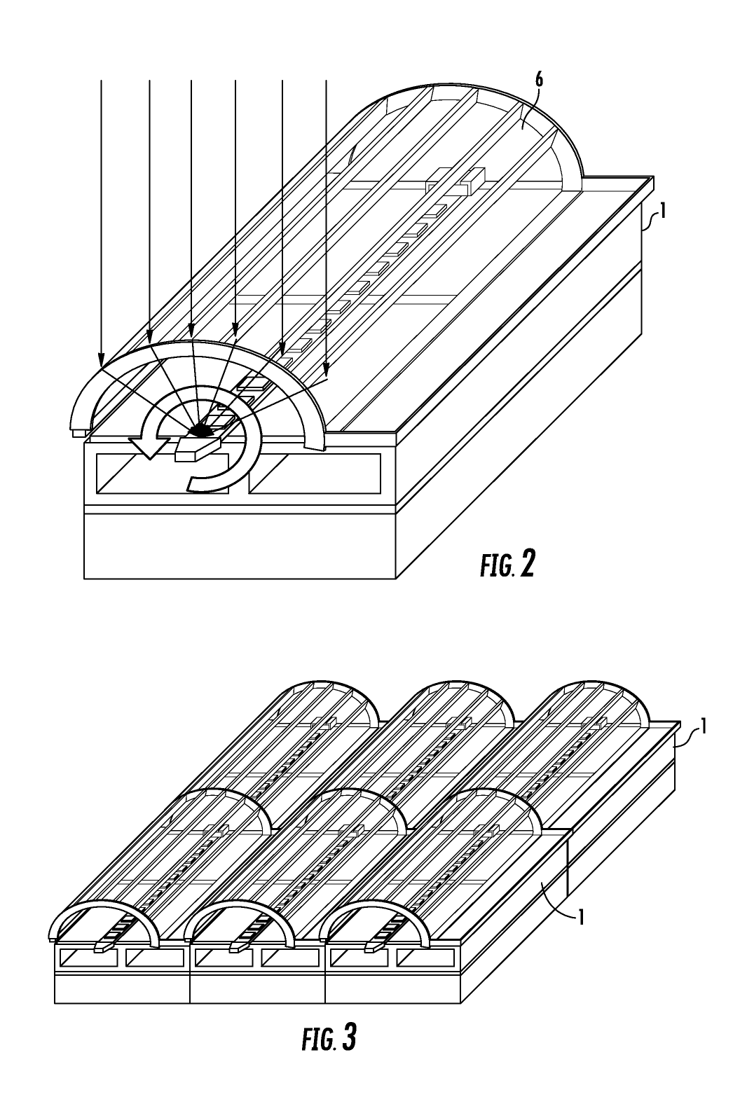

According to the first exemplary embodiment, the power yield of the multi-cellular photovoltaic module 4 of each tile is enhanced by the presence of a transparent cap 6 of the hollow body 1. This forms a cylindrical lens that concentrates or focuses the incident radiation over a strip coinciding with the active surface of the multi-cellular photovoltaic module 4, as symbolically depicted in FIG. 2.

Optionally, the photovoltaic module 4 may be pivotally mounted on pins for allowing the active surface plane of the cells to be oriented toward the sun by an electromechanical actuator of a sun tracking subsystem. This option is symbolically depicted by a circular arrow in FIGS. 1 and 2. In any case, the semi-cylindrical shape of the transparent cap is used for focusing the light beam onto the active areas of the photovoltaic cells.

In general, the various embodiments set forth herein may advantageously systematically conjugate or join together the electrical, thermal-hydraulic and mechanical portions to facilitate actuation of a sun tracking action or motion by the photovoltaic fixtures, while also providing for a highly modular rooftop layout. The drawings related to a first exemplary embodiment schematically indicate the pivoting movement of the photovoltaic module of each tile. Simultaneous orientation of the photovoltaic modules of all the tiles on a rooftop slope may be actuated by one or more step motors, which may be installed either at the vertex or at the base of the rooftop slope, or in another position of the columns of tiles to effectively track the sun during daylight to maximize the yield of photovoltaic energy conversion.

FIG. 3 shows the modular coupling of tiles by columns disposed along the direction of the rooftop slope, and flanked from one flank of the rooftop to the opposite flank. The transparent caps 6 may be made of a plastic resistant to atmospheric agents and to solar radiation, or of glass or other similarly resistant optical material. Moreover, besides defining a cylindrical lens that concentrates the light over the respective light sensing strip area of the photovoltaic module 4, the cap 6 may be shaped with suitable geometrical edge features along the respective lower and upper sides and along the two flanks, relative to the arrangement of the rooftop tiles over the roof slopes. It may be further adapted to provide effective mounting and mutual locking of upper and lower ends as well as flanks, to thereby ensure stability and an effective rain-proofing of the roof. This may be done in a functionally similar manner to that of traditionally implemented tiling with ordinary clay, concrete or molded plastic tiles.

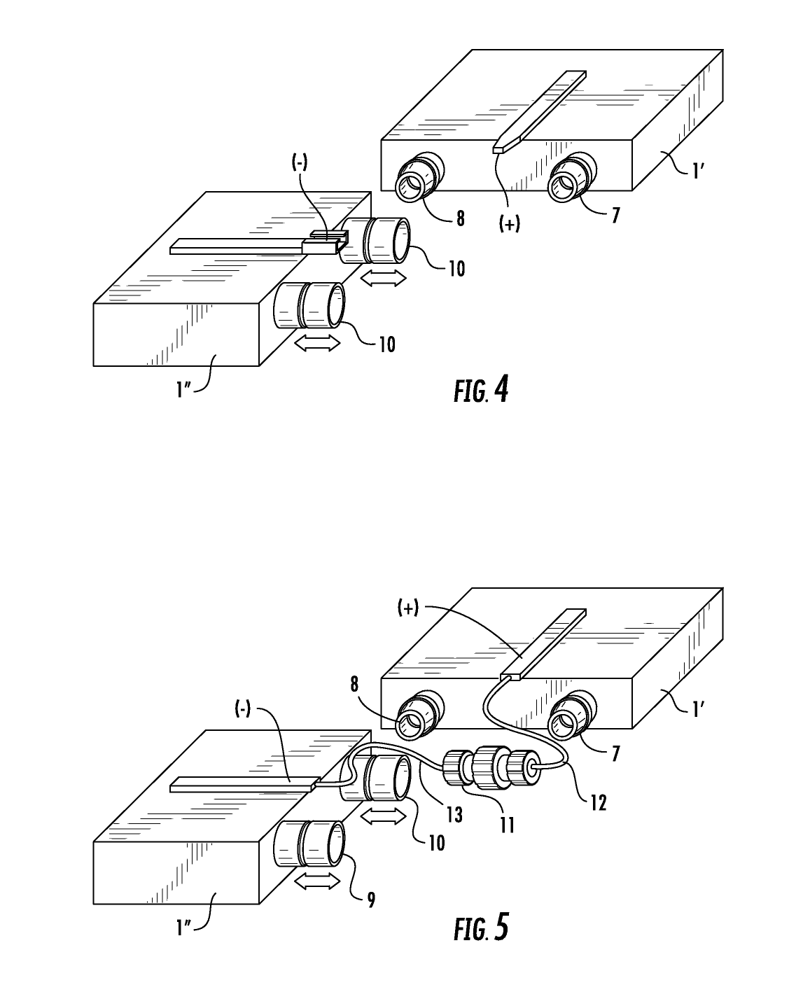

FIG. 4 shows two roof tiles of the present disclosure on which the hydraulic and electrical connections are visible on the end walls thereof. These connections are made while laying the tiles one after the other, forming columns of tiles that are substantially hydraulically and electrically connected in series, extending from the base to the vertex of the slope.

As shown, in a lower end wall of the roof tile 1′ two quick-action hydraulic nipples 7 and 8 may be provided, which in the present example are both male parts, along with a positive electrical connector (+) terminal of the photovoltaic module of the tile 1′, which in the example shown is also male. The lower end side of the tile 1′ thus equipped eventually couples with the upper end side of the next tile 1″ of the column. In an upper end wall, female nipples 9 and 10 are present for hydraulic connection, which may be adapted to snap onto the male nipples 7 and 8 of the first tile 1′. A negative electrical connector (−) terminal of the photovoltaic module of the tile 1″, which has a female configuration, is adapted to be joined to the male connector (+) of the first tile 1′.

FIG. 5 schematically shows an alternative exemplary embodiment of a series electrical connection of the modules of two adjacent tiles employing a weather proof connector 11. The two joinable parts are weather-proof terminations of respective isolated cables 12 and 13, which are connected to the positive and negative terminals, respectively, of the two photovoltaic modules of adjacent tiles 1′ and 1″.

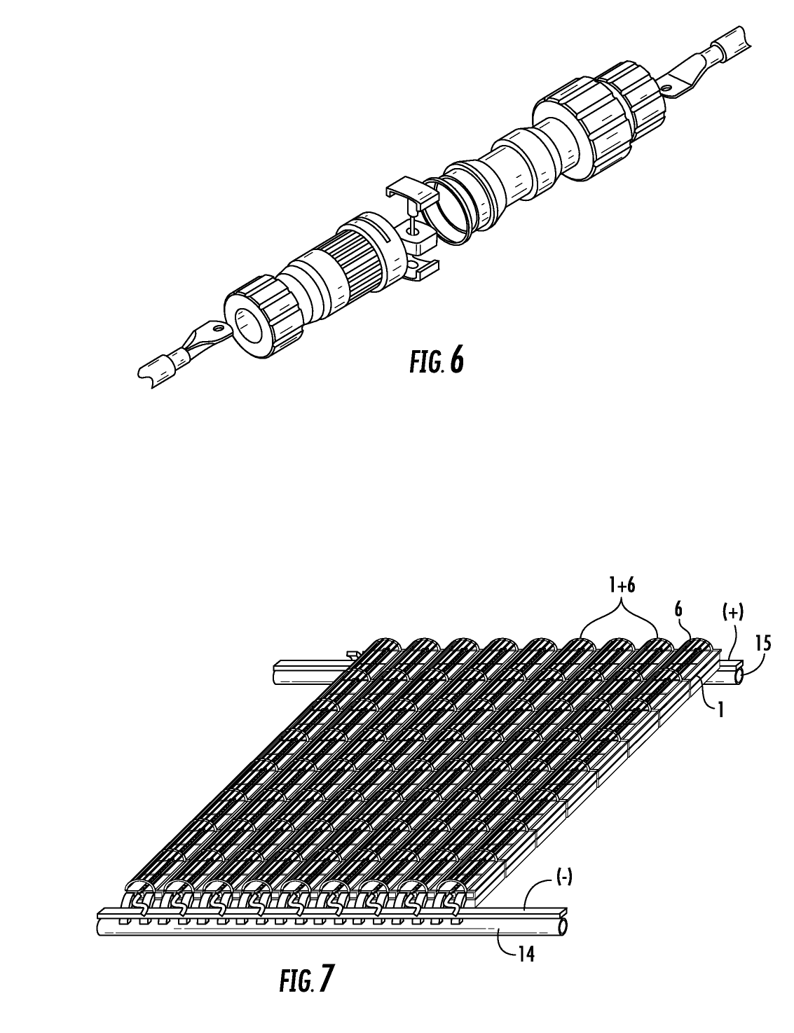

FIG. 6 is view of a weather proof connector 11 for cables 12 and 13 for series-connecting photovoltaic modules of tiles laid one next to the other along a column of tiles extending from the base to the vertex of the roof slope.

FIG. 7 shows a rooftop slope tiling configuration including modular multifunctional tiles in accordance with the present disclosure, and with a plurality of hydraulically and electrically series-connected tiles in columns in the slope direction. Moreover, the tiles are hydraulically connected to a hot water outlet manifold 14 running at the base of the slope, and to a cold water inlet manifold 15 running along the vertex of the slope and electrically connected in parallel to an anodic bus (−) and to a cathodic bus (+), also running respectively at the base and at the vertex of the slope.

Referring additionally to FIGS. 8 through 13, an alternative exemplary embodiment of the system is shown in which concentration of the solar radiation onto the active surface of the photovoltaic module incorporated in each tile is implemented by reflection instead of transmission. This is done by using a surface of an adjacent tile that is purposely made reflective, i.e., by using a flanking tile to reflect and concentrate light on the photovoltaic module of an adjacent tile. This may be particularly advantageous when the sun is low on the horizon, and with a sun-tracking hinged mirror when the sun is high in the sky. This alternative embodiment is particularly well suited for rooftop slopes which, instead of facing toward the ecliptic, face in a direction parallel or almost parallel to the ecliptic.

FIG. 8 is a three-dimensional cross sectional view of multifunctional rooftop tile adapted for reflection illumination of its photovoltaic module. In this example, the hollow body 1 of the tile also has two inner parallel flow channels 2 and 3 for a heat transfer fluid or water to be heated, oriented in the slope direction.

In contrast to the embodiments of FIGS. 1-7, there is no transparent cap adapted to establish the necessary surmounts and mutual grip or connection arrangements between adjacently laid tiles to ensure rain-proofing of the roof. Rather, these geometrical features along the four sides of each tile are defined in the hollow body 1 itself. For lateral coupling, the hollow body 1 is provided with a side lip 17 which couples with or overlies the flank of the adjacently laid tile, while the mounting between adjacent tiles laid along a column in the direction of the rooftop slope may be realized as shown with greater detail in FIG. 12.

According to this alternative embodiment, each tile (i.e., each hollow body 1) has an upper surface with a windblown wave crest 16 parallel to the flanks of the tile, the up-wind surface of which will be oriented towards the ecliptic. Such a convex up-wind surface of the crest has a broken line outer profile, a segment 18 of which corresponds to a locally concave surface provided with a reflective coating. The inclination of this concave reflective surface is designed to reflect and concentrate the solar radiation onto the active cell areas of a multi-cellular photovoltaic module 4 located in the lee side concavity of the wave crest 16, parallel and under the crest of an up-wind side flanking tile.

A reflective surface may even be used as a dichroic mirror reflecting the visible and UV spectrum of the incident solar radiation and substantially transparent to the IR spectrum of the solar radiation. This will accordingly contribute to heating, as in the preceding embodiment, of either water or a different heat transfer fluid flowing inside the hollow tile body 1. Also, in this embodiment the multi-cellular photovoltaic module has positive and negative terminals (+) and (−) for electrical connection in series with other photovoltaic modules.

Automatic sun tracking may in this case be realized with an over-structure 19, for example of reinforced plastic material, applied over the concave part of the upper surface of the hollow body 1. This may comprise an orientable reflective wing 20, hinged along the hinge line 21, and connected to a fastening part of the over-structure 19 onto the concave part or lee side of the upper surface of the hollow body 1.

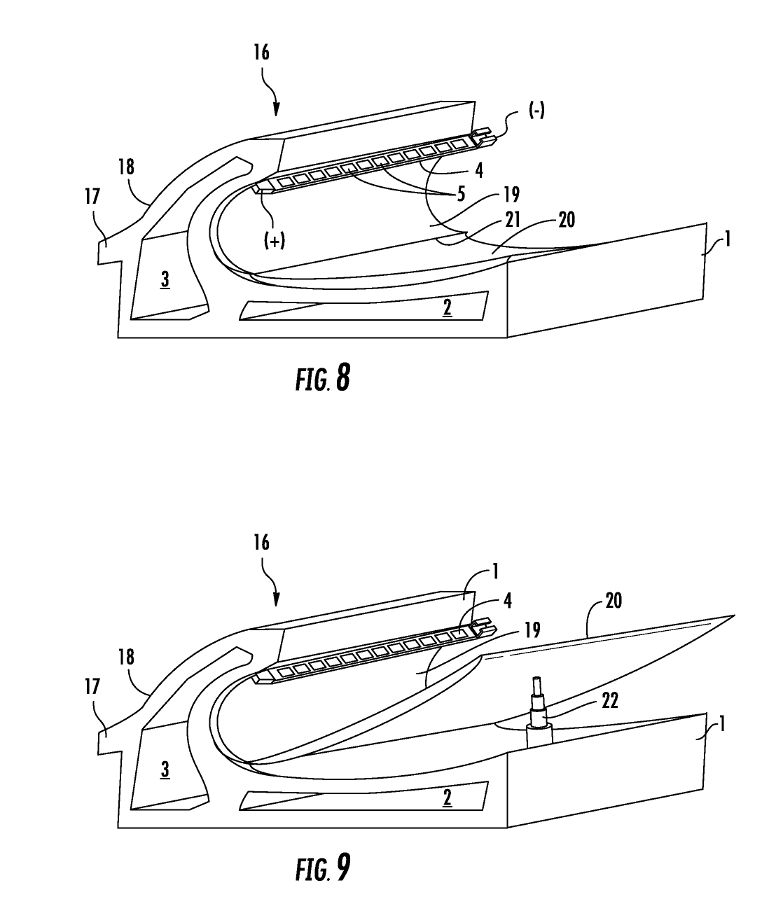

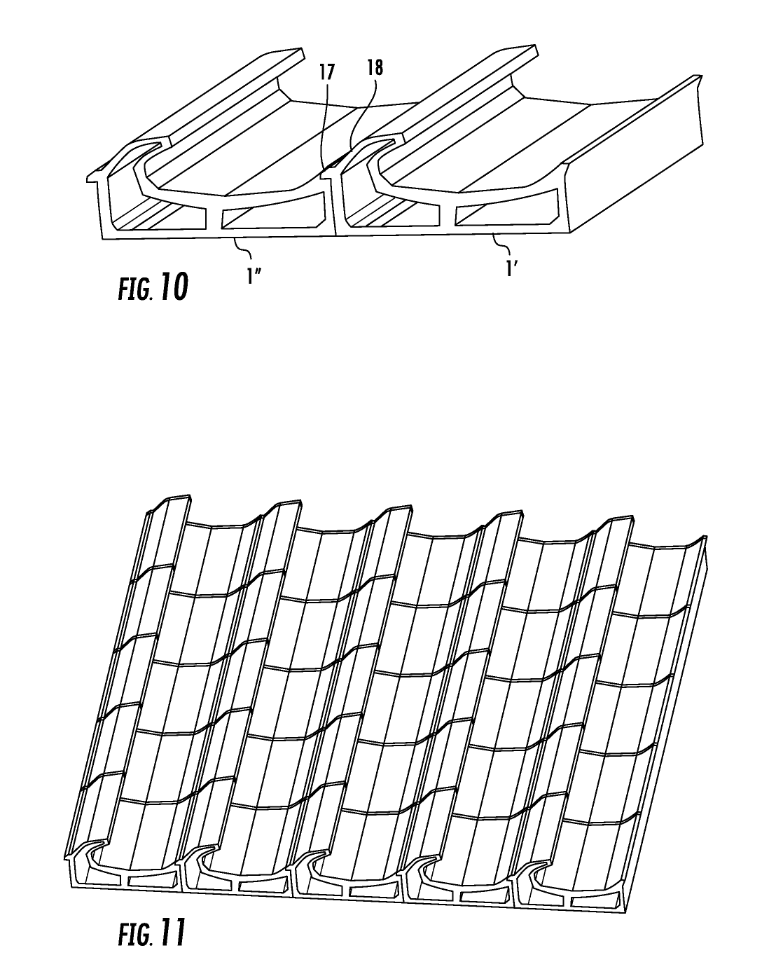

An effective sun tracking to concentrate the reflected variation on the active surfaces of the photovoltaic module 4, may for example be implemented, as shown in FIG. 9, by a cylinder or bellows 22. This may be actuated by the heat transfer fluid itself circulating within the flow channel 2 of the hollow body 1 of the tile by adjusting its pressure. Of course, instead of a cylinder or bellows 22, electromechanical actuators may be used, and the over-structure 19 may be made in the form most suited to the type of tracking actuators to be used.

FIG. 10 shows the mounting or joining that is established between flanking tiles along rows of tiles adapted to ensure stability of the tiling and rain proofing of the roof. The lateral lip 17 surmounts or overlies the flank of the adjacent tile, preventing rain from infiltrating through the tiling of the roof.

The coordination between the fixed reflective surface 18 of the hollow body of each tile with the position of the photovoltaic module under the crest of the upper surface of the body 1 of the adjacent tile on the up-wind side is shown in FIG. 10. When the sun is relatively low on the horizon looking in the direction of a flank of the rooftop slope, the reflecting wings 20 for illuminating the active surfaces of the cells 5 of the photovoltaic module 4 may be less useful, as they are necessarily fully abated onto the upper surface of the tiles. This is partly offset by the light reflected and concentrated from the fixed surface 18 of the flanking tile on the lee side. The inclination of this flanking tile is such that is reflects the incident light onto the active area of the photovoltaic module 4 of the flanking tile on the upstream side.

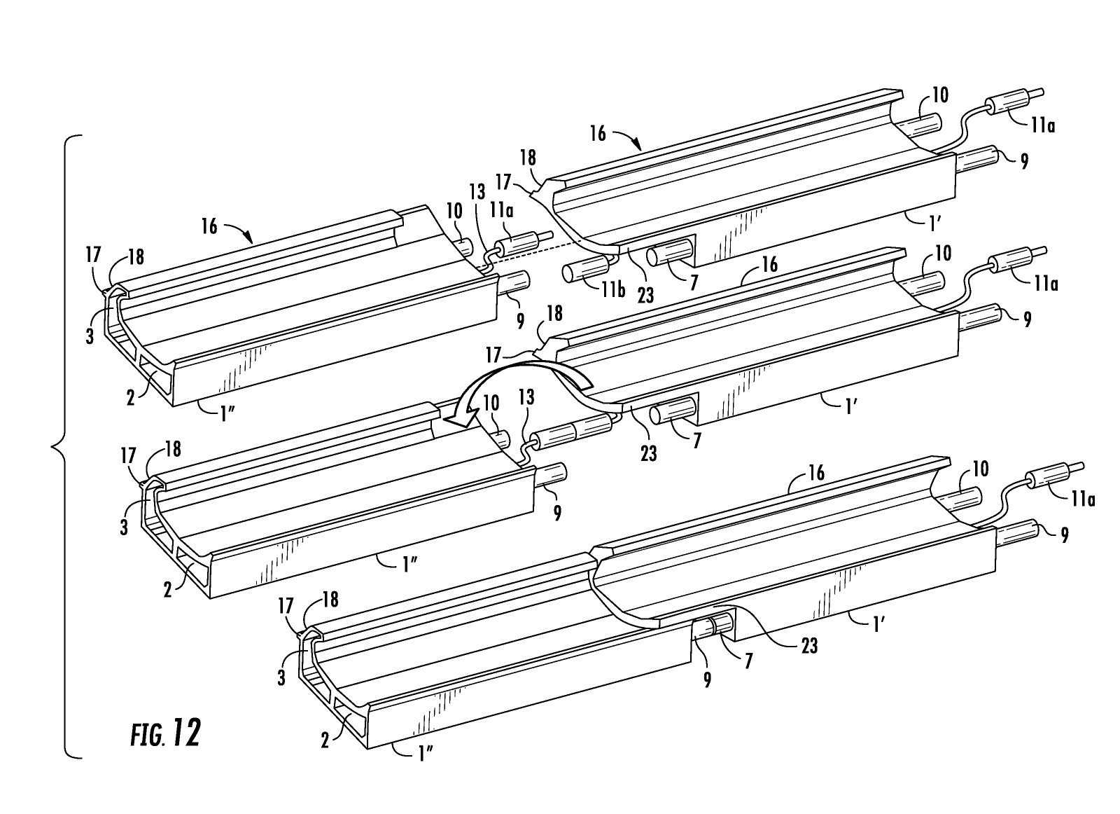

FIG. 11 is a schematic view showing an implementation of the tiling made with the multifunctional roof tiles made according to this alternative embodiment. FIG. 12 illustrates coupling of roof tiles to one another in forming columns of tiles oriented in the slope direction. Hydraulic couplings 7, 8, 9 and 10 are adapted to establish continuity of flow of heat transfer fluid through the inner channels 2 and 3 of the hollow body 1 of the tiles in a way similar to that which was described in connection with the first embodiment. Weather proof electrical connectors 11a and 11b are for connecting the photovoltaic modules of all the tiles forming a column oriented in the slope direction in series. Furthermore, it may be seen that the coupling among adjacent tiles along a column establishes the necessary surmounting or overlap of the up slope tile 1′ over the down slope tile 1″ to provide rain-proofing. To this end, the tiles have a lower side gutter 23 of a size and dimensions to be adapted to surmount and to hook onto the upper surface of the down slope tile 1″, which is coupled to the up slope tile 1′.

In this case, as in the previously described example, the hydraulic nipples of the first tile at the base of the slope will connect with two hydraulic couplings of an outlet manifold of the heat transfer fluid circuit running along the base of the slope. The hydraulic nipples of the last tile of the column will connect with two hydraulic couplings of an inlet manifold of the heat transfer fluid circuit running along the vertex of the slope. Moreover, corresponding weatherproof electrical connectors may establish the electrical connection to a negative bus running at the base of the slope and to a positive bus running along the vertex, or vice-versa.

That which is claimed is:

1. A photovoltaic and thermal solar energy conversion rooftop tiling system employing multifunctional tiles adapted to be laid over a roof slope for constituting a rainproof covering, each tile comprising
a hollow body of rectangular footprint of a material adapted to absorb IR radiation, having heat transfer fluid circulation channels defined therein and oriented in the roof slope direction;
a photovoltaic cell strip module extending in the slope direction from a lower end side to an upper end side of the hollow body and a negative sign terminal and a positive sign terminal of series connected photovoltaic cells of said strip module at said upper and lower end sides, respectively, active cell surfaces coinciding with the focus of either a cylindrical lens portion of a transparent top cover fastened to the hollow body or of a reflective cylindrical mirror surface atop the hollow body;
weather proof electrical connectors and quick-action hydraulic couplings in a lower end side wall and in an upper end side wall of the hollow body, adapted to connect electrically in series said photovoltaic cell strip modules and hydraulically in series said heat transfer fluid circulation channels of column-wise laid tiles, and to an inlet manifold and to an outlet manifold of circulation of said heat transfer fluid and to a negative sign bus and to a positive sign bus.

2. The system of claim 1, wherein the tiles are laid onto a rooftop isolation comprising a layer of expanded or fibrous material topped by a reflective film or foil.

3. The system of claim 1, wherein said transparent cover defines a cylindrical transmission lens and has portions projecting beyond the perimeter of the underlying hollow body, said projecting portions of the transparent cover constituting surmounting and underlying grip fixtures matching with corresponding underlying and surmounting grip fixtures of adjacent tiles cooperating in forming and mechanically stabilizing said rainproof covering.

4. The system of claim 1, wherein said photovoltaic cell strip module is pivotally sustained along said focus of the cylindrical transmission lens and electrical actuating means orient the plane of said active surfaces of the photovoltaic cells of the pivoting strip module to track the sun position for maximum electrical current yield.

5. The system of claim 1, wherein the upper surface of the hollow body has a wind-blown wave crest profile, said photovoltaic cell strip module extending parallel under the crest on the lee side of it, the active surfaces of the cells of the photovoltaic cell strip module being illuminated by reflection of the solar radiation on a concave cylindrical portion of the generally convex up-wind surface of said wind-blown wave crest profile of the adjacent tile on the lee side, or on a hinged reflector having a concave reflective surface that is lifted from a rest position abated onto the surface of the underlying hollow body on the lee side of the wind-blown wave crest for tracking the sun position for maximum electrical current yield.

6. The system of claim 5, wherein the rotation of said hinged reflector wing is actuated by a hydraulic cylinder or bellows by varying the pressure of the heat transfer fluid flowing in at least an inner channel of the hollow tile body.
